(19) United States
(12) Patent Application Publication
(10) Pub. No.: US 2025/0390639 A1
(43) Pub. Date: Dec. 25, 2025

(54) COMPUTERIZED TECHNIQUES FOR OPTIMIZED ROOM LAYOUT GENERATION

(71) Applicant: Pantheon AI, Inc, San Francisco, CA (US)

(72) Inventors: David MACE, San Francisco, CA (US); Tiger SUN, San Francisco, CA (US)

(21) Appl. No.: 18/927,472

(22) Filed: Oct. 25, 2024

Related U.S. Application Data
(60) Provisional application No. 63/662,165, filed on Jun. 20, 2024.

(51) Int. Cl. G06F 30/27; G06F 30/13

(52) U.S. Cl. CPC G06F 30/27; G06F 30/13

(57) ABSTRACT

Systems, methods, apparatuses, and computer program products of a user interface configured for automated generation and optimization of room layout designs. One method may include determining a relative position token for each of a plurality of elements according to a function of at least one relative position token of at least one other element. Each relative position token comprises at least one discrete non-Cartesian value of each of the elements. The method further comprises determining a Cartesian position for each of a plurality of elements according to a function of at least one of the relative position tokens to generate a room layout; displaying, in an interactive computerized user interface, at least one generated room layout; and based upon input from the interactive computerized user interface, transmitting at least one of the generated plurality of room layouts and a request for a selection of the transmitted room layouts.

### CROSS-REFERENCE TO RELATED APPLICATION

This application claims the benefit of U.S. Provisional Application No. 63/662,165, filed Jun. 20, 2024. The entire content of the above-referenced application is hereby incorporated by reference.

### TECHNICAL FIELD

Some example embodiments may generally relate to computer-aided architectural designs, and more specifically, to systems and/or methods of a user interface configured for automated generation and optimization of room layout designs.

### BACKGROUND

Traditionally, architects design floorplans through a creative and iterative process that integrates multiple considerations, such as spatial requirements, functional requirements, aesthetic preferences, and building regulations. Architects begin by identifying the type of building needed by the client (e.g., residential, commercial, industrial, educational, etc.), the size and types of rooms needed, budget constraints, and any room-specific requirements (e.g., accessibility features).

### SUMMARY

In accordance with some example embodiments, a computerized method for automatically generating an optimized room layout design may include determining a relative position token for each of a plurality of elements according to a function of at least one relative position token of at least one other element. Each relative position token comprises at least one discrete non-Cartesian value of each of the elements. At least one relative position token corresponds with an element that is affixed to a wall. The method may further include determining a Cartesian position for each of a plurality of elements according to a function of at least one of the relative position tokens to generate a room layout. The method may further include displaying, in an interactive computerized user interface, at least one generated room layout. Based upon input from the interactive computerized user interface, the method may further include transmitting at least one of the generated plurality of room layouts and a request for a selection of at least one of the transmitted room layouts.

In accordance with certain example embodiments, an apparatus for automatically generating an optimized room layout design may include means for determining a relative position token for each of a plurality of elements according to a function of at least one relative position token of at least one other element. Each relative position token comprises at least one discrete non-Cartesian value of each of the elements. At least one relative position token corresponds with an element that is affixed to a wall. The apparatus may further include means for determining a Cartesian position for each of a plurality of elements according to a function of at least one of the relative position tokens to generate a room layout. The apparatus may further include means for displaying, in an interactive computerized user interface, at least one generated room layout. The apparatus may further include means for based upon input from the interactive computerized user interface, transmitting at least one of the generated plurality of room layouts and a request for a selection of at least one of the transmitted room layouts.

In accordance with various example embodiments, a non-transitory computer readable medium may include program instructions that, when executed by an apparatus, cause the apparatus to perform at least a method for automatically generating an optimized room layout design for automatically generating an optimized room layout design. The method may include determining a relative position token for each of a plurality of elements according to a function of at least one relative position token of at least one other element. Each relative position token comprises at least one discrete non-Cartesian value of each of the elements. At least one relative position token corresponds with an element that is affixed to a wall. The method may further include determining a Cartesian position for each of a plurality of elements according to a function of at least one of the relative position tokens to generate a room layout. The method may further include displaying, in an interactive computerized user interface, at least one generated room layout. The method may further include based upon input from the interactive computerized user interface, transmitting at least one of the generated plurality of room layouts and a request for a selection of at least one of the transmitted room layouts.

In accordance with some example embodiments, a computer program product may perform a method for automatically generating an optimized room layout design for automatically generating an optimized room layout design. The method may include determining a relative position token for each of a plurality of elements according to a function of at least one relative position token of at least one other element. Each relative position token comprises at least one discrete non-Cartesian value of each of the elements. At least one relative position token corresponds with an element that is affixed to a wall. The method may further include determining a Cartesian position for each of a plurality of elements according to a function of at least one of the relative position tokens to generate a room layout. The method may further include displaying, in an interactive computerized user interface, at least one generated room layout. The method may further include based upon input from the interactive computerized user interface, transmitting at least one of the generated plurality of room layouts and a request for a selection of at least one of the transmitted room layouts.

In accordance with certain example embodiments, an apparatus may include at least one processor and at least one memory storing instructions that, when executed by the at least one processor, cause the apparatus at least to determine a relative position token for each of a plurality of elements according to a function of at least one relative position token of at least one other element. Each relative position token comprises at least one discrete non-Cartesian value of each of the elements. At least one relative position token corresponds with an element that is affixed to a wall. The at least one memory and instructions, when executed by the at least one processor, may further cause the apparatus at least to determine a Cartesian position for each of a plurality of elements according to a function of at least one of the relative position tokens to generate a room layout. The at least one memory and instructions, when executed by the at least one processor, may further cause the apparatus at least to display, in an interactive computerized user interface, at least one generated room layout. The at least one memory and instructions, when executed by the at least one processor, may further cause the apparatus at least to, based upon input from the interactive computerized user interface, transmit at least one of the generated plurality of room layouts and a request for a selection of at least one of the transmitted room layouts.

In accordance with various example embodiments, an apparatus may include determining circuitry configured to perform determining a relative position token for each of a plurality of elements according to a function of at least one relative position token of at least one other element. Each relative position token comprises at least one discrete non-Cartesian value of each of the elements. At least one relative position token corresponds with an element that is affixed to a wall. The apparatus may further include determining circuitry configured to perform determining a Cartesian position for each of a plurality of elements according to a function of at least one of the relative position tokens to generate a room layout. The apparatus may further include displaying circuitry configured to perform displaying, in an interactive computerized user interface, at least one generated room layout. The apparatus may further include transmitting circuitry configured to perform, based upon input from the interactive computerized user interface, transmitting at least one of the generated plurality of room layouts and a request for a selection of at least one of the transmitted room layouts.

### BRIEF DESCRIPTION OF THE DRAWINGS

For a proper understanding of example embodiments, reference should be made to the accompanying drawings, wherein:

FIG. 1 illustrates an example of a user interface for interacting with an automatic room layout generator according to various example embodiments;

FIG. 2 illustrates a method for predicting element parameters that may be performed by a computing device according to some example embodiments;

FIG. 3 illustrates a method for rotating elements that may be performed by a computing device according to certain example embodiments;

FIG. 4 illustrates a method for generating a room layout that may be performed by a computing device according to certain example embodiments;

FIG. 5 illustrates an example of a flow diagram of a method according to various example embodiments; and

FIG. 6 illustrates an example of a network device according to some example embodiments.

### DETAILED DESCRIPTION

It will be readily understood that the components of certain example embodiments, as generally described and illustrated in the figures herein, may be arranged and designed in a wide variety of different configurations. Thus, the following detailed description of some example embodiments of systems, methods, apparatuses, and computer program products of a user interface configured for automated generation and optimization of room layout designs is not intended to limit the scope of certain example embodiments, but is instead representative of selected example embodiments.

Architects may develop initial room layout designs in a logical manner with a variety of software tools, such as drafting tools and computer-aided design (CAD) software (e.g., AutoCAD, SketchUp, DraftSight). Architects may also consider ease of movement through the room layout between various elements.

After creating an initial room layout satisfying the minimal requirements, architects may review the design with the client, and revise according to any feedback or concerns they may have. Other specialists may be consulted as well, such as interior designers and Heating, Ventilation, and Air Conditioning (HVAC) engineers, on how the design may be improved based on their specializations. This iterative exchange and redesign process can be extremely inefficient.

Generating highly optimal layouts of immovable and movable elements for a room is highly complex because the number of layout options is extraordinarily large. For example, for a 20′×20′ room with 25 elements that can each be placed along a 1″ grid, the number of possible orientations is 10119. Generating such a large number of orientations can require a large number of computing resources that are mostly wasted.

Certain example embodiments described herein may have various benefits and/or advantages to overcome the disadvantages described above. For example, certain example embodiments may improve the automatic generation of optimized room layouts by providing a user interface that facilitates an iterative, interactive generation process by minimizing or eliminating inefficient generation of undesirable layouts. Thus, certain example embodiments discussed below are directed to improvements in computer-related technology.

Certain example embodiments described herein may relate to automated generation of optimized room layouts including a plurality of room elements. Room elements may include any element that can be present in a building, such as base cabinets, upper cabinets, countertops, fridges, freezers, stoves, sinks, chairs, couches, beds, heaters, televisions, lamps, windows, doors, vents, switches, outlets, mirrors, rugs, dressers, tables, microwaves, dishwashers, washers, dryers, tables, chairs, cabinets, TVs, bookshelves, couches, lab benches, table-top equipment, equipment, and many other elements that are present in rooms or spaces within buildings. Room elements may be placed in any of the placements that elements may be present in spaces. Room elements may be fixed to a wall. Room elements may be fixed to the floor/ceiling. Room elements may be movable but adjacent to a wall. Room elements may be movable.

In general, an optimized room layout simultaneously optimizes between many conflicting requirements, such as element distances from doors/windows/corners, relative desired rotations of elements, gap space between elements, whether elements are touching, walkway spacing within the space, conflicts when opening elements, conflicts with window and door positions, countertop space next to elements, alignment of elements, depth of countertops, corner cabinet orientations, element styles, cabinet sizes, relative height and vertical placement, element subtype and style, and others.

Furthermore, a room may be enclosed by walls, have an open wall or multiple walls, or have no walls and just be a designated space. Rooms may be in the shape of arbitrary polygons or shapes, including those with diagonal, concave, and/or curved boundaries.

Some example embodiments may relate to generating room layouts for any room type that is known, including a kitchen, single toilet bathroom, multi-toilet bathroom, half-bathroom, full bathroom, master bathroom, laundry room, garage, bedroom, master bedroom, living room, dining room, individual office, conference room, kitchenette, mechanical room, electrical room, utilities room, attic, fitness room, classroom, hotel room, open office space, single-room apartment, center rooms of an apartment, home office, guest room, laundry room, storage room, pantry, garage, basement, attic, playroom, library or reading room, mudroom, sunroom, gym or fitness room, media or entertainment room, walk-in closet, balcony or patio room, reception area or lobby, conference room or meeting room, office room (private and open plan), break room or lunch room, restroom or washroom, server room or data center, mail room, storage room or supply room, training room, executive suite, waiting room, copy room, gym or fitness center, janitor's closet, retail space, showroom, kitchenette, auditorium, game room or recreation room, co-working space, classrooms, laboratories, lecture halls, libraries or reading rooms, gymnasiums, auditoriums, cafeterias or canteens, staff rooms, principal or administrator's offices, nurse's offices or medical rooms, patient rooms (private and shared), operating rooms (OR), emergency rooms (ER), waiting rooms, X-ray or imaging rooms, pharmacies, research rooms, utility rooms, storage rooms, and chapels or prayer rooms, production floor, warehouse or storage area, loading dock, quality control room, machinery room, break room, control room, server room, maintenance room, office space, laboratory, workshop, locker room, restroom, conference room, shipping and receiving room, cleaning room, security room, cafeteria, utility room, exhibition room, gallery, reading room, archives room, workshop room, performance hall, green room, control room, multipurpose room, box office, cloakroom, lecture room, research room, conservation room, art studio, media room, restoration room, café, cafeteria, children's activity room, security room, gift shop, dining area, private dining room, bar area, kitchen, wine cellar, game room, smoking room, VIP lounge, banquet hall, dance floor, restrooms, washrooms, changing room, locker room, staff break room, storage room for supplies, reception area, ticket booth, back office, event space, beverage station, sanctuary, worship hall, prayer room, confession room, meditation room, sacristy, nave, choir room, fellowship hall, nursery room, library or study room, meeting room, classroom for religious education, baptistry, office for clergy, candle room, cloakroom, community kitchen, event hall, storage room, restroom, fitness room, cardio room, weightlifting room, yoga studio, swimming pool area, locker room, sauna, steam room, massage room, aerobics room, climbing wall room, boxing ring area, indoor court, outdoor field, equipment room, training room, medical room, spectator seating area, snack bar, pro shop, administrative office, consultation room, examination room, treatment room, procedure room, waiting room, reception area, pharmacy, physical therapy room, radiology room, laboratory, recovery room, inpatient room, hydrotherapy room, counseling room, acupuncture room, massage therapy room, steam room, sauna room, herbal treatment room, and changing room, ticketing area, check-in area, baggage claim area, security checkpoint, and other rooms for a variety of building types.

Certain example embodiments may generate one or more room layouts that may be presented in a user interface (UI) to a user. The user may edit a layout, reject/accept a layout, generate more layouts that are similar, and generate more layouts from scratch. The user may change input parameters, causing the output room layout to change. These new output room layouts may be displayed as multiple options that the user can select from. The new output room layout may be automatically updated in the representation of the building. The layout(s) may be transmitted and/or displayed to an architect, user of the space, and/or owner of the space. Based upon input from the interactive computerized user interface, at least one of the generated plurality of room layouts may be transmitted and a request for a selection of at least one of the transmitted room layouts may be transmitted. The layout(s) may be edited on a computer after being generated. An input to the layout generation may be a partial layout. A user may perform an iterative process by a combination of steps of generating options, reviewing options, and editing options.

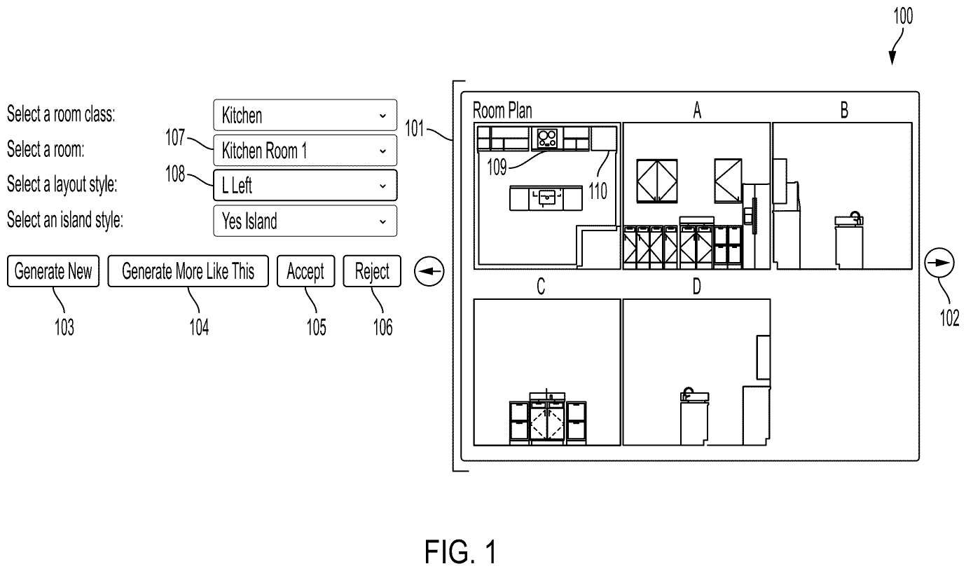

In various example embodiments, a UI may be configured to facilitate automatic generation of room layouts, and allow a user to quickly select, approve, and reject generated room layouts. The user may also modify a specific room layout automatically. FIG. 1 depicts UI 100 configured to enable a user to request automatic generation of at least one room layout, and view the resulting generated at least one room layout.

Room layout 101 may be an automatically generated layout that may be displayed to the user in UI 100. In various example embodiments, room layout 101 may be displayed in a format similar to that depicted in FIG. 1, or in any alternative format to convey the information to the user of room layout 101. Such formats may be two-dimensional (2D) or three-dimensional (3D), and may represent a single level or multiple levels. Room layout 101 may be editable or non-editable; editable layouts may enable the user to correct any errors in the generated room layout. These formats may contain the complete layout or a partial layout. As an example, the generated room layouts may be moved through multiple subsequent UIs, programs, and file formats to edit the automatically generated layout. In various example embodiments, UI 100 may be a 2D display of room layout 101, which may include other elements/spaces. In certain example embodiments, UI 100 may be a display of a 3D model of the layout. In some example embodiments, UI 100 may display the layout in an architectural plan set view.

Element 102 may be a button configured to allow the user to scroll between generated layouts. In some embodiments, room layout 101 may be automatically generated before the user clicks element 102. In some embodiments, room layout 101 may be automatically generated when the user clicks element 102. In some embodiments, room layout 101 may be viewable directly in UI 100, and the user may select between them.

Button 103 in UI 100 may be configured to allow the user to generate a new layout that will be displayed to the user in UI 100. Similarly, button 104 in UI 100 may be configured to allow the user to generate a new layout that is similar to room layout 101 currently displayed to the user. Button 105 in UI 100 may be configured to allow the user to accept the current room layout 101. Button 106 in UI 100 may be configured to allow the user to reject the current room layout 101. In some embodiments, when the user clicks button 106, a new generated room layout 101 may be shown in UI 100, either from the set previously generated or a new layout. Dropdown selector 107 may be configured to allow the user to select which space to generate the layout for. In various embodiments, the options provided by dropdown selector 107 may be rooms, spaces, and/or floorplans. In some embodiments, the user may select a room via a dropdown, a previous screen where the room is clicked on, or another method to select the room. Constraint 108 may enable the user to set various constraints for room layout 101. In some embodiments, constraint 108 may have more than one constraint. In various embodiments, a constraint can be a slider, a number that is typed in, an input file, an option from a dropdown menu, or any other method to specify an input.

Object 109 may be a nonmovable fixture generated by the automatic room layout generator and displayed by UI 100. Object 110 may be a movable element generated by the automatic layout generator and displayed by UI 100.

In certain example embodiments, a partial room layout may be input into the automatic layout generator, and the automatic layout generator may generate the remaining portion of the layout. The current elements in the partial layout may be removed from the set of elements to be inserted. Thus, whenever a layout is generated, the starting layout may be a partial layout, rather than an empty layout.

In some example embodiments, the user may interactively generate layouts with the automatic layout generator by deleting some elements from the generated layout, marking an area to be changed, and/or marking an area to not be changed, and then requesting the automatic layout generator to regenerate the layout. This iteration cycle may be performed once or multiple times. The automatic layout generator may generate the layout for multiple rooms at the same time. The layout of the rooms may also be generated in the same step as a floorplan is generated.

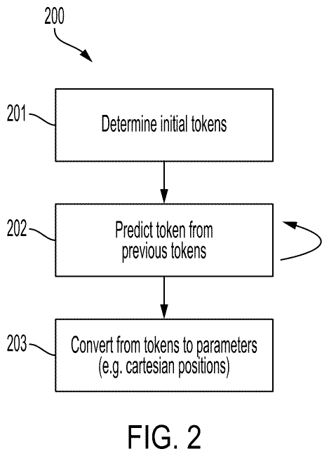

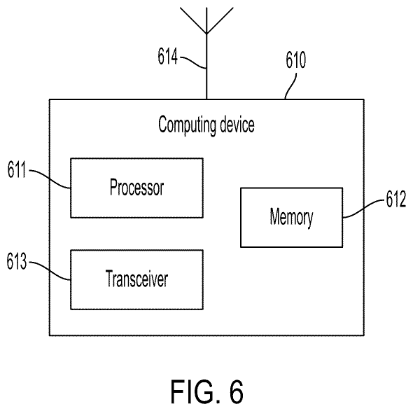

FIG. 2 illustrates an example of a flow diagram of a method 200 for predicting element parameters (i.e., positions) that may be performed by a computing device, such as computing device 610 illustrated in FIG. 6, according to various example embodiments.

In step 201, a room and already-present elements (e.g., doors, windows) may be parameterized into a set of tokens.

In step 202, an element parameter may be predicted based on a set of tokens representing the room and already-present elements. Step 202 may be repeated a predetermined number of times, with the input tokens being updated to include the already-predicted element parameters.

In step 203, the tokens may be converted to parameters (e.g., Cartesian coordinates, cartesian sizes, other information representing the element's orientation within cartesian space, and other element information). A Cartesian position may be determined for each of a plurality of elements according to a function of at least one of the relative position tokens to generate a room layout.

Certain example embodiments may predict an optimal position key for one or more elements of the room layout. For example, a position key may be a token that represents a relative placement of an element. The position key may specify a relative placement to the available area along a wall in the space. The position key may specify a corner position. The position key may specify a position relative to a certain corner. The position key may specify a position relative to a center of a certain wall. The position key may be a relative placement to another element already placed in the space (e.g., fixed elements such as a door). Each position key may be converted to a Cartesian position within the room via a function ‘f’. As elements are placed, ‘f’ may output a different Cartesian position for a given input, based on the elements' positions for elements already in the floorplan. Elements may be affixed to walls or other surfaces. Elements may be movable and not affixed to a surface.

Certain embodiments may predict a rotation key for one of more elements of the room layout. Certain embodiments may predict a key that specifies to stretch the element until it reaches a wall. Certain embodiments may predict a key to expand or shrink an element either as a relative portion or to a preset size. Certain embodiments may predict a key specifying whether to flip an element over the horizontal, vertical, or both axes. Certain embodiments may use these predicted outputs as inputs for subsequent predictions of other element parameters (i.e., a predicted rotation may be an input for predicting a position). Each element parameter may be predicted by a separate model. Element parameters may be predicted by a single model, which may choose which parameter to predict next and/or only predict a subset of parameters for certain elements.

Examples of position keys are element placement position keys, room input keys, and/or layout parameter keys.

As an example, element placement position keys may include any of: for each wall, the leftmost open position on the wall for a given vertical plane; for each wall, the rightmost open position on the wall for a given vertical plane; for each wall, a fixed number of inches (e.g., 18) towards the wall's center from the leftmost open position on the wall, for a given vertical plane; for each wall, a fixed number of inches (e.g., 18) towards the wall's center from the rightmost open position on the wall, for a given vertical plane; for each wall, the middle position, for a given vertical plane; for each currently placed element, the position to the left of the element; for each currently placed element, the position to the right of the element; and for each currently placed element, the position a fixed number of inches in a given direction from the element.

As an example, “left/leftmost/right/rightmost” may refer to the direction to one's left/right if standing with one's face to the wall. For an element, “left/leftmost/right/rightmost” may refer to the direction to one's left/right if standing on top of the element and facing the same direction as the element's front.

Room input keys may specify any aspects of the room, such as shape, utilities, windows/doors, etc. Examples of room input tokens may include any of a token that represents whether the room is square, has the longest dimension in the left-right axis, or has the longest dimension in the front-back direction; a binary token for whether the room should have an island; a token for each wall that represents whether the wall is within a set of distance ranges (e.g., <=4 ft, >4-6 ft, >6-8 ft, >8-12 ft, >12-20 ft, >20 ft); a token for whether the room square footage is within a set of area ranges (e.g., <=30 sqft, >30-60 sqft, >60-100 sqft, >100-200 sqft, >200-300 sqft, 300+ sqft; a token for whether there is a gas input on the left, front, right, or back wall; a token for whether there is a water input on the left, front, right, or back wall; a token for whether there is a second door on the left, front, right, or back wall; a token for whether there is an ethernet connector on the front, left, right, or back wall; a set of tokens representing which wall positions contain windows; a set of tokens representing which wall positions contain doors. In some example embodiments where there are utility connections on multiple walls, one may be chosen at random. A model may be trained on all position keys or a subset of position keys. These values may change to represent the remaining available space as room elements are placed.

Layout parameter keys may specify aspects of the room's layout, including any of: whether there is a countertop layout of a given type (e.g., linear on the back wall, L on the back and left walls, U on the left and back and right walls); and whether there is an island in the room and which wall it is placed relative to. Layout parameter keys may be specified by the computer (e.g., randomly) and/or by the user via the UI.

Tokens may be converted into numeric vectors, then these vectors may be concatenated and/or inputted to a model. Each vector may contain a set of binary values, where the value at position ‘n’ in the vector represents whether the token equals the index ‘n’ element in a list of potential tokens. The token vectors may be determined by a model.

Relative position keys may form a denser representation of the placements of elements in space versus Cartesian positions; this may enable an accurate model to be trained with a tractable amount of data.

To predict a position of an element within a space, a relative position token may be predicted from the set of relative position tokens of elements already in a space. A plurality of elements may have their relative position tokens predicted by sequentially predicting the relative position token for each element by a model inputted with the set of relative position tokens of elements already placed in the space. A relative position token may be determined for each of a plurality of elements according to a function of at least one relative position token of at least one other element. Each relative position token may comprise at least one discrete non-Cartesian value of each of the elements. The inputs and outputs of this model may also include other element parameters.

The tokens inputted to and outputted from the model may be a concatenation of an identification/name and/or a relative position token of an element. This may enable the algorithm to predict relative positions of elements in an arbitrary order.

In various example embodiments, a variety of algorithms may be used to predict a string token from a sequence of string tokens as input. For example, a long short-term memory network (LSTM) may be used to predict the next element in the sequence. As another example, a probabilistic decision tree may be used to predict the next element in the sequence. As another example, one or more neural networks may predict subsequent elements. If the input would have length less than the size accepted by the prediction algorithm, then the input may be buffered with buffer tokens at the start of the sequence until the sequence is the adequate length.

For various subsets of cases (e.g., different rooms), the optimal prediction model may be determined individually from a set of model options (e.g., a set of LSTMs and probabilistic decision trees). A variety of models (including different hyperparameters) may be trained on a training dataset, and then run on a test dataset; the accuracy of the models may be compared to determine which model is the most accurate.

Certain example embodiments may train an LSTM. The model may include an embedding layer configured to convert tokens into vectors. The embedding size may be 16, or any of a variety of other values. The embedding layer may be connected to an LSTM layer, which may be connected to another LSTM layer. Both LSTM layers may have a hidden size of N. The final LSTM layer may be connected to a fully connected (e.g., linear) layer, which may produce a vector of logits (i.e., raw prediction scores) for each token in the vocabulary. The predicted token may be the one corresponding to the highest logit. In other embodiments, one or more embedding layers, LSTM layers, and fully connected layers may be combined to form a model.

In some example embodiments, the value of N may be determined by starting at 32, training and evaluating the model, and repeating on each higher multiple of 2 (e.g., 32, 64, 128, etc.) until the test evaluation accuracy does not improve from the previous multiple of 2 to the current multiple of 2.

In various example embodiments, batch size may be 64, learning rate may be 0.001, and the number of epochs (i.e., one pass through the training data) may be any value (e.g., 20). The input size may be 100 (which may be big enough to enter all elements and inputs for a room). Sequences of size less than 100 may be trained by buffering with a buffer token at the start of the sequence until the sequence is length 100. The optimizer may be an adaptive moment estimation (ADAM) optimizer. The loss function may be the cross entropy loss function. The variety of other values may be used for the batch size, learning rate, number of epochs, input size, and other model and meta parameters. Other optimizers and loss functions may be used.

Certain example embodiments may determine an optimal decision tree, wherein the splitting criteria may be Gini impurity (i.e., configured to estimate number of different classes in a node). The optimal decision tree may be allowed to have unlimited depth. String tokens may be converted to integer IDs to enable the model to have integers rather than strings as the input and output.

Some example embodiments may determine the optimal LSTM and determine the optimal probabilistic decision tree. The optimal model may be determined to be the one with the highest accuracy on the test dataset, regardless of model type.

Other example model types include a hidden Markov model (HMM), other neural networks, LSTMs with other architectures and/or hyperparameters, recurrent neural networks (RNN), transformers, and any other model type that may predict the next element in a sequence.

In some embodiments, all of the non-cabinet elements may be placed first, and all of the cabinet elements may be placed next; these cabinets may fill pre-defined spaces between elements or along layout lines. In some embodiments, the amount of space remaining in a layout line, an aspect (e.g., width) of the element to the left of the layout line, and/or an aspect (e.g., width) of the element to the right of the layout line may be inputs to a model that is used to predict the next placed element and its position.

In various example embodiments, the style of each element may be predicted. For example, an algorithm (e.g., LSTM) may be trained that predicts the next element's style from the set of styles of other elements. This algorithm may be any algorithm that can predict an output string from a vector of input strings. Each style key may be a string (e.g., light wood with panel style 1, cherry wood with panel style 2). To predict both a position and style, an optimal model may be selected from a set of tested algorithms (e.g., LSTMs and decision trees).

A separate model may predict the positions and the styles. The same model may predict the positions and styles (which may enable the model to make better predictions since the style and position of elements are interrelated). One model output may be the relative position key of the element, and the second output may be the style key of the element. The inputs may be a concatenation of the sequence of element relative position keys and the sequence of the element style keys. As an example, for an LSTM, the input size may be 200, and the input may be buffered, as discussed throughout this disclosure. Examples of styles include the color of a product, the SKU of a product, the shape of a product, the material of a product, the aesthetics of a product, a combination of these factors, and any other information that a designer would classify a product with.

In various example embodiments, models may predict a probability for a set of next element parameters (e.g., positions, styles). A single layout may be generated by probabilistically determining the next element parameter, and then repeating this process until the room is complete. This process may be repeated as many times as the user desires or a preset number of times (e.g., 10,000) to generate a variety of layouts that can be displayed to the user. In some example embodiments, only the first layout may be displayed, while in other example embodiments, multiple of the layouts may be displayed.

When a position of an element is predicted as the position relative to open space, the function to convert from relative position to Cartesian position may account for the intersection with other elements (e.g., the ‘leftmost’ position of an element to be placed at a vertical position from 5′ to 7′ may be the leftmost position that does not intersect with any other elements at the vertical positions from 5′ to 7′, while ignoring any elements that are not at vertical positions from 5′ to 7′).

A corner, edge, or other position may be calculated as a function of the polygon of available space to place an element (e.g., accounting for other elements' occupied space and required surrounding space to use those elements).

The height and/or vertical position of an element may be predicted.

In some example embodiments, a scoring function may be used on each of the automatically generated plans. The plans may be sorted and/or filtered by their scores. At least one high scoring (i.e., desirable) plan may be shown to the user. The highest scoring plan(s) may be shown to the user in the UI. The user may move between high scoring plans via the UI.

The prediction model may search a dataset for an exact match or near match of the currently placed elements subsequence to predict the next element. If there are multiple samples in the dataset that are as close of a match, then the model may return a random sample from these multiple samples. An exact match means all elements are the same. A close match means a specific small number of elements (e.g., 1 or 2) are different. In certain embodiments, one of more sequences of tokens representing good room layouts may be retrieved and converted into layouts for a room; the mapping of tokens to cartesian positions may result in different layouts for different rooms.

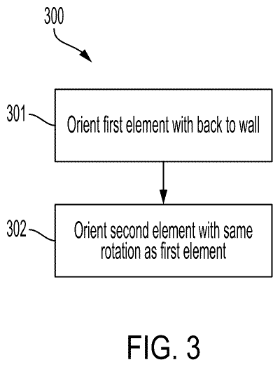

FIG. 3 illustrates an example of a flow diagram of a method 300 for rotating elements that may be performed by a computing device, such as computing device 610 illustrated in FIG. 6, according to various example embodiments.

At step 301, if the relative position key for an element E1 represents a relative position to the open position along a wall, then element E1 may be oriented with its back to the wall.

At step 302, if the relative position key for an element E1 is a relative position to another element E2, then element E1 may be oriented with the same rotation as element E2.

“Layout lines” for elements may be placed; these layout lines may be part of linear wall layouts (along all or part of a given wall), L shape layouts, U shaped layouts, G shaped layouts, or any other layout composed of lines. In some example embodiments, the layout lines of elements for a room may be selected randomly, randomized across a set of generated layouts, or specified by the user. After a layout line is created, it may be filled with elements; these elements may be placed by predicting relative position keys, and then converting each element's position key to a Cartesian position in the line.

In various example embodiments, when two layout lines intersect, a corner element (e.g., a cabinet) may be added at that intersection position, and the remaining space in the lines may be reduced by the space of the corner element. The corner element may be selected from the set of possible styles by a variety of methods (e.g., random selection from the set of possible elements that are suitable for that position). The elements placed in the lines may be rotated such that their backs face a specific direction.

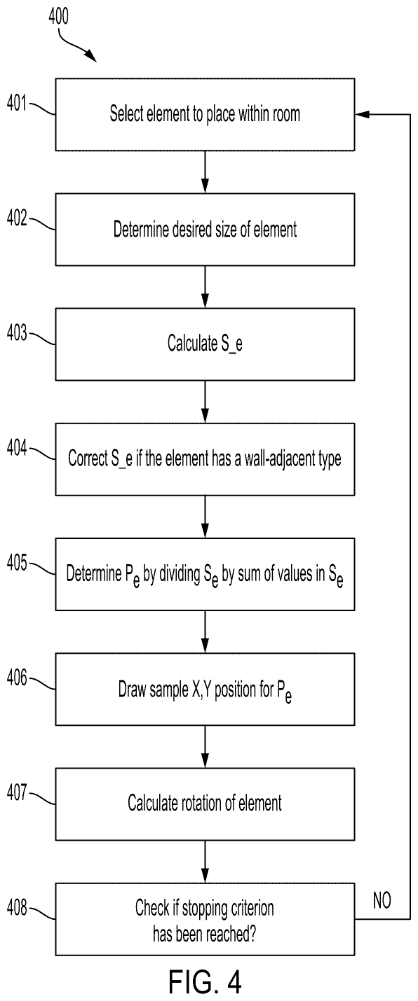

FIG. 4 illustrates an example of a flow diagram of a method 400 for generating a room layout that may be performed by a computing device, such as computing device 610 illustrated in FIG. 6, according to various example embodiments.

At step 401, the method may include randomly selecting a next element to place. The selected element may be removed from the set of elements remaining to be placed.

At step 402, the method may further include calculating/determining a desired size of the element. The size of the element may be chosen as a random member from the set of possible sizes of the element from the list of known possible sizes.

At step 403, the method may further include calculating Sₑ, a distribution of positions to place the center of element ‘e.’ Sₑ may be 1D, 2D, or 3D.

At step 404, the method may further include, if the element is a wall-adjacent type, setting Sₑ to 0 at all positions that are not half of the element's depth away from a wall; the positions may be rounded to the nearest gridline or integer.

At step 405, the method may further include calculating a probability function across space (Pₑ) by dividing the distribution Sₑ by the sum of all values in Sₑ. Sₑ and Pₑ may be discretized into matrices that store the values of Sₑ and Pₑ at specific positions (e.g., on a 1″ spaced grid). Sₑ and Pₑ may be not discretized and only stored in continuous distribution form. The sum of elements in Sₑ may be approximated by finding the average of a large number of (e.g., 100) values of Sₑ for random x,y within the room's boundary, then multiplying by the area of the room.

At step 406, the method may further include drawing a sample X, Y position from the 2D probability distribution Pₑ to place element ‘e.’

Sₑ(p) may be

$${\sum }_{i = 1}^{M} ( p ; {μ}_{i} , {Σ}_{i} ) .$$

Each [symbol] Ni may be a normal distribution. [symbol] may be replaced by any other function that inputs a point and outputs a value. ‘p’ may be an input point to a distribution, which may be in 1D, 2D, or 3D. μᵢ may be the position of an ‘intriguing point’. Σᵢ may be the variance of a distribution. Σᵢ may be set as follows: the standard deviation may be 2 feet in all directions for utility connections, 3 feet in all directions for random points, 1 foot for lights, 3 feet for corners, 3 feet for the center of the room, and 2 feet in all other cases.

At step 407, the method may further include, if the element is a wall-adjacent type, calculating the rotation of the element as the rotation that would place the element's back to the wall that is half of the element's depth away from the element. The method may further include, if the element is not a wall-adjacent type, choosing a rotation randomly from the set (e.g., 0°, 45°, 90°, 135°, 180°, 225°, 270°, 315°, 360°).

At step 408, the method may further include returning to step 401 unless a stopping criterion has been reached. Examples of stopping criteria are: (1) there are no more elements to place, (2) the iterations that this procedure has been performed equals a constant (e.g., 20) multiplied by the number of elements to be placed.

In certain example embodiments, the set of intriguing points for an element ‘e’ may include electrical outlet positions if the element needs an electrical outlet; water connection positions if the element needs a water connection; gas connection positions if the element needs a gas connection; positions of lights; corners of the polygons of available space where elements have not been placed yet; the centroid of the room; the positions of the windows; the positions of the posts; randomly selected points in the room; the positions of lights (and/or the positions on specific horizontal planes below the lights); the positions of the doors; the positions of other elements in the room; and the positions a distance in a given direction from another element in the building.

Sₑ and/or Pₑ may be distributions (e.g., in continuous or discretized matrix format) that have the same value at all points that do not have a value of zero. Sₑ and/or Pₑ may be sums of at least one dirac delta function with an offset. A dirac delta function is a function that is zero everywhere except at a single point, where it is infinitely high, such that its integral over the entire real line is equal to one. Pₑ may be determined or inputted without calculating Sc.

A room's internal elements may be generated automatically after the room is placed in a floorplan (and/or after the room is created or specified to be created).

In various example embodiments, a large number (e.g., 1 million) potential layouts may be generated and scored. The layouts may be sorted by their score and the highest scoring layout may be shown to the user (e.g., via UI 100 discussed above).

Certain example embodiments may score a given set of room layouts by combining a set of functions. These functions may be combined into a holistic function. For example, the combination function may be calculated according to

$$J ( x ) = {∧}_{i = 1}^{n} {b}_{i} ( x ) * {Σ}_{i = 1}^{n} {c}_{i} ( x ) ,$$

where bᵢ(x) are binary functions that output 0 or 1, and cᵢ(x) are continuous functions that output between 0 and 1. As another example, the functions may be combined in a weighted sum. For example, one or more of the weights may be manually set (either by the user or as a preset) or the optimal weights may be determined from evaluating the accuracy of different weights when evaluated on a labelled dataset. In another example embodiment, all of the binary and continuous functions may be multiplied together (or their logs summed together). In other example embodiments, only a subset of these functions may be used to calculate J. In other example embodiments, all of the functions may be summed together, including the binary functions. The sub-functions of J may include any of the functions described in this disclosure.

For each function, if the function described below does not result in a value between 0 and 1, where 1 is a better value and 0 is a worse value, then a second function may be applied after to map the first function's output to this range. Various embodiments may include linear, logarithmic, polynomial, exponential, and other known function types that can map outputs. The function may also trim the output between a lower/upper bound.

E is the set of elements in the room. Some embodiments may determine how well the elements fit the user's desired distances between certain pairs of elements. The user's input may be a desired distance for each of a set of element pairs. The function may be calculated according to ƒ(x)={square root over (Σ_{A}_{_{x,y}}_{≠null}(D_{e1,e2}−A_{e1,e2})²)}, where D_{e1,e2} may be the distance between elements e1 and e2, and A_{e1,e2} may be the user's desired distance between elements e1 and e2 (where an A value of null means the user has not specified this pair). In all functions, some embodiments may replace the exponent 2 with P, and replace the square root with the exponent 1/P.

In various example embodiments, the final function output may be normalized according to 1−ƒ(x){square root over (Σ_{A}_{_{x,y}}_{≠null}(BD−A_{e1,e2})²)}, where BD is the largest distance between points in the room.

Various functions may be used to calculate the distance measure used throughout this disclosure. An example distance function is the flood-fill distance, which is the distance while only travelling via a set of fixed length movements in the horizontal and vertical directions. Another example distance function is the Euclidean distance, which is the length of a straight line between the start and end points. The normalizing factors used in functions may use the same distance calculation method as their corresponding function being normalized. Distances used in various parts of the disclosure may be the distance in a 1D line, 2D plane, or 3D region.

Throughout this disclosure, an alternative coordinate system may be used instead of Cartesian positions.

In certain example embodiments, D_{e1,e2} may be the distance in the vertical direction, A_{e1,e2} may be the desired vertical distance, and BD may be the largest height in the room.

In various example embodiments, D_{e1,e2} may be a binary metric denoting whether elements are directly next to each other. A value of 0 may indicate that elements are adjacent, while a value of 1 may indicate that elements are not adjacent. The value of BD may be 1. A_{e1,e2} may be a binary input on whether pairs of elements are desired to be touching; 0 may mean they are supposed to be touching, and 1 may mean they are supposed to not be touching.

In certain example embodiments, D_{e,s} may be the distance from element e to the nearest wall along the element's side ‘s’ (e.g., front, back, left, right). A_{e,s} may be similarly the desired distance from element e to the nearest wall along the element's side ‘s.’ BD may be the largest flood-fill distance between points in the room.

In some example embodiments, Dₑ₁ may be [I(e1,s1), I(e1, s2), I(e1, s3), I(e1, s4)], where I(e,s) is the distance from element e to the room's side s, divided by the distance from s to the opposite side (e.g., the max width or depth of the room). Aₑ₁ may be the desired percentage of distance of the element from each side, and BD may be 1.

Certain example embodiments may determine how well the elements fit the distribution of distances between elements in a dataset of room layouts. For each pair of elements in the dataset, a mean (μₑ_{₁}_{,e}_{₂}) and standard deviation (σₑ_{₁}_{,e}_{₂}) may be calculated from the set of distances between this pair of elements across the dataset. For example, the function may be calculated as ƒ(x)=Σ_{e1,e2∈ExE}Zₑ_{₁}_{,e}_{₂}(D_{e1,e2}), where E is the set of elements in the room,

$${Z}_{{e}_{1} , {e}_{2}} ( d ) = \vert \frac{d - {μ}_{{e}_{1} , {e}_{2}}}{{σ}_{{e}_{1} , {e}_{2}}} \vert .$$

In some example embodiments, function Zₑ_{₁}_{,e}_{₂}(d) may be capped at 3, and the final function output may be normalized as f(x)/λ_{e1,e2∈ExE}3.

In certain example embodiments, D_{e1,e2} may only be the distance in the vertical direction, and μ and σ may only be measured in the vertical direction.

In some example embodiments, D_{e,s} may be the distance from element e to the nearest wall along the element's side ‘s’ (e.g., front, back, left, right). Z_{e,s} may similarly be the Z-score (e.g., the number of standard deviations away from the mean) for the dataset's distances from element e to the nearest wall along the element's side ‘s’.

In various example embodiments, Dₑ₁ may be calculated as [I(e1,s1),I(e1,s2),I(e1,s3),I(e1,s4)], where I(e,s) may be the distance from element e to the room's side s, divided by the distance from s to the opposite side (e.g., the max width or depth of the room). I(e,s) may be the percentage of the room's dimension that the element is away from a wall on a certain side. Zₑ₁ may be the dataset-determined percentage of distance from each side for element e1 (e.g., certain elements are often placed a farther spacing from walls on certain of the elements' sides).

Certain example embodiments may calculate how well the elements fit the user's desired relative rotations between certain pairs of elements. The user's input may be a desired relative rotation for each of a set of element pairs. The function may be calculated as ƒ(x)={square root over (Σ_{A}_{_{x,y}}_{≠null}k(R_{e1,e2},A_{e1,e2})²)}, where R_{e1,e2} may be the rotation difference between elements e1 and e2, and A_{e1,e2} may be the user's desired rotation difference between elements e1 and e2 (where a value of null may mean the user has not specified this pair). R and A may be converted to positive values; for instance, a −90° difference is specified as a 270° difference. In addition, k(θ₁,θ₂)=min(|θ₁−θ₂|, 360°−|θ₁−θ₂|). In some example embodiments, the final function output may be normalized by 1−ƒ(x)/{square root over (Σ_{A}_{_{x,y}}_{≠null}180²)}.

Certain example embodiments may determine how well the elements fit the set of rotations between elements in a dataset of room layouts. For each pair of elements in the dataset, the frequency of a band of rotations between elements e1 and e2 in the dataset may be calculated as

$${FR}_{e 1 , e 2} ( y ) = \vert \{ x ∈ {L}_{e 1 , e 2} \vert ℋ \cdot round ( \frac{x}{ℋ} ) = y \} \vert ,$$

where L_{e1,e2} is the list of relative rotations for elements e1 and e2 in instances in the dataset. The rotation between a given pair of elements is always a positive number (e.g., 270° instead of −90°). As an example, [symbol] may be 15°. In another example, [symbol] may be any number from 0 to 180°. Larger datasets may be used with smaller values of [symbol] , and small datasets may be used with larger values of [symbol] . A scoring function may be calculated as ƒ(x)=Σ_{e1,e2∈ExE}FR_{e1,e2}(O_{e1,e2}), where O_{e1,e2} is the rotation between elements e1 and e2. The final function output may be normalized according to ƒ(x)/|E×E|.

Certain example embodiments may calculate the quantity of gaps between cabinet elements, which may be normalized by the function ƒ(x)=1−min(x,3), where x may be the number of gaps.

Some example embodiments may calculate the area of space in gaps between cabinet elements, which may be normalized by the function ƒ(x)=1−min(x,10), where x may be the area of space in gaps and may be measured in square feet.

Various example embodiments may calculate the alignment of element edges, including cabinet edges. This may be calculated according to ƒ(x)=|{(lᵢ,lⱼ)∈S×S|lᵢ∥lⱼ, i≠j}|, where S is the set of all edges of elements' bounding boxes. As an example, N lines that are all parallel to each other may be counted N×(N−1) times. As another example, each line may be removed from the set once it is paired with a parallel line, so N parallel lines will only be counted N−1 times. As another example, the function may be normalized by ƒ(x)/|S×S| or ƒ(x)/|S|.

In various embodiments, at least one element may be generated randomly or may be generated independently of other elements' aspects. In certain embodiments, the relative positions and/or Cartesian positions of elements may be stored and used at a later time for space.

The relative position keys may be represented in the embeddings of a model such that the output of a single model is Cartesian positions.

In certain example embodiments, element styles may refer to the SKU of a product or a variety of a product (e.g., 5-cabinet/4 cabinet, L/linear couch) or a material/finish of an element. For example, some example embodiments may determine whether the frequency of element styles in a space matches the distribution of element styles in a user's desired frequency (which may either be inputted in dense or sparse formats). Various example embodiments may determine whether the frequency of element styles matches the distribution of element styles from a dataset of element styles from spaces. M is the list of desired frequency (which may be based on a dataset or a user's input) for each element's style.

In various example embodiments, ƒ(x)=M·K, where M may be the list of desired frequency for each element's style; the frequencies in M may sum to 1; K may be a list of the frequency of the elements in the room, listed in the same order as the element frequencies in M; and the frequencies of K may sum to 1. f(x) may calculate the similarity of the frequencies of styles in the space and the dataset.

In various example embodiments, f(x) may be other functions that calculate a distance between two vectors (e.g., Euclidian distance, Manhattan distance, Jaccard index). In some example embodiments, M and K may be lists of frequencies of element pairs (which may be represented in either dense or sparse format), rather than single elements. In other example embodiments, M and K may be lists of frequencies of length-3 combinations of elements (which may be represented in either dense or sparse format), rather than single elements or pairs of elements.

Certain example embodiments may use a binary function to determine whether elements overlap, including any area required to properly use the element (e.g., the area required to open the door of a cabinet). This binary function may be calculated as whether Area (U_{P}_{ᵢ}_{∈p}Pᵢ)==Σ_{P}_{ᵢ}_{∈p}Area(Pᵢ), where P is the set of the polygon bounding box for the elements, including any area required for use of the element. The set P may include fixed elements, including windows and doors, and may include the areas necessary to utilize those elements. For windows, this polygon may span across the width and height of the window and the depth may be the necessary polygon space in front of a window to operate it. The area required to use an element may be defined by building code, a preset, or the user. For doors, this area goes from floor to ceiling and may be the area around a door required to be empty mandated by building code.

Some example embodiments may determine whether there is a corner cabinet at each corner that has cabinets on both sides of the corner; whether all fixtures, including cabinets, are placed against walls or within islands and peninsulas; whether there is a countertop over all cabinets; and/or whether there is a countertop next to each fixture of adequate dimensions to use the fixture. To calculate whether adequate countertop space is available to use the fixtures, it may be calculated whether U_{EP}_{ᵢ}_{∈EP}EPᵢ\U_{CP}_{ᵢ}_{∈CP}CPᵢ==Ø and Area(U_{EP}_{ᵢ}_{∈EP}EPᵢ)==Σ_{EP}_{ᵢ}_{∈EP}Area(EPᵢ), where EP may be the set of polygons of necessary adjacent countertop surfaces to elements, and CP may be the set of polygons of the countertops in the room. These functions may determine whether the areas adjacent to fixtures that must be countertops are actually countertops, and that these areas do not overlap between fixtures.

Various example embodiments may determine whether there is a walkway of adequate width that reaches each element. This may be calculated according to H=R\U_{P}_{ᵢ}_{∈P}Pᵢ where R is the room polygon and P is the set of the bounding box polygon for each element in the room. H2 may be the Minkowski difference of H and C, where C is a circle of radius 1″ smaller than half of the minimum walkway width mandated by building code. H3 may be the Minkowski sum of H2 and C. H3 may be a multi-polygon, and H4 may be the subset of polygons from H3 that touch a door. A score function may return 1 if every element's polygon (for elements that must be reachable) shares an edge with the H4 polygon; otherwise, a score function may return 0.

Certain example embodiments may determine whether all elements requiring a utility connection are within reach of a utility connection. Utility connections may include electrical outlets, gas connections, water connections, and ethernet connections. This function may be 1 if all elements are within the allowable range of their necessary utility connections; otherwise, this function may be 0.

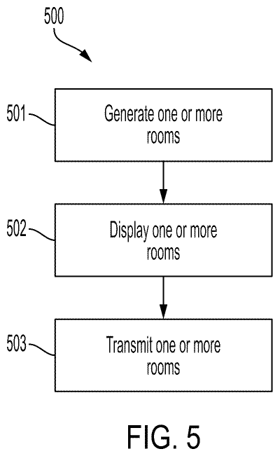

FIG. 5 illustrates an example of a flow diagram of a method 500 for generating one or more room layouts that may be performed by a computing device, such as computing device 610 illustrated in FIG. 6, according to various example embodiments.

At step 501, the method may include automatically generating one or more rooms.

At step 502, the method may include displaying, in an interactive computerized user interface, at least one generated room layout.

At step 503, the method may include transmitting at least one of the generated plurality of room layouts and a request for a selection of at least one of the transmitted room layouts.

FIG. 6 illustrates an example of a system according to certain example embodiments. In one example embodiment, a system may include multiple devices, such as, for example, computing device 610.

Computing device 610 may include one or more of a mobile device, such as a mobile phone, smart phone, personal digital assistant (PDA), tablet, or portable media player, digital camera, pocket video camera, video game console, navigation unit, such as a global positioning system (GPS) device, desktop or laptop computer, single-location device, such as a sensor or smart meter, or any combination thereof.

Computing device 610 may include at least one processor, respectively indicated as 611. Processor 611 may be embodied by any computational or data processing device, such as a central processing unit (CPU), application specific integrated circuit (ASIC), or comparable device. The processors may be implemented as a single controller, or a plurality of controllers or processors.

At least one memory may be provided in one or more of the devices, as indicated at 612. The memory may be fixed or removable. The memory may include computer program instructions or computer code contained therein. Memory 612 may independently be any suitable storage device, such as a non-transitory computer-readable medium. The term “non-transitory,” as used herein, may correspond to a limitation of the medium itself (i.e., tangible, not a signal) as opposed to a limitation on data storage persistency (e.g., random access memory (RAM) vs. read-only memory (ROM)). A hard disk drive (HDD), random access memory (RAM), flash memory, or other suitable memory may be used. The memories may be combined on a single integrated circuit as the processor, or may be separate from the one or more processors. Furthermore, the computer program instructions stored in the memory, and which may be processed by the processors, may be any suitable form of computer program code, for example, a compiled or interpreted computer program written in any suitable programming language.

Processor 611, memory 612, and any subset thereof, may be configured to provide means corresponding to the various blocks of FIGS. 2-5. Although not shown, the devices may also include positioning hardware, such as GPS or micro electrical mechanical system (MEMS) hardware, which may be used to determine a location of the device. Other sensors are also permitted, and may be configured to determine location, elevation, velocity, orientation, and so forth, such as barometers, compasses, and the like.

As shown in FIG. 6, transceiver 613 may be provided, and one or more devices may also include at least one antenna, illustrated as 614. The device may have many antennas, such as an array of antennas configured for multiple input multiple output (MIMO) communications, or multiple antennas for multiple RATs. Other configurations of these devices, for example, may be provided. Transceiver 613 may be a transmitter, a receiver, both a transmitter and a receiver, or a unit or device that may be configured both for transmission and reception.

The memory and the computer program instructions may be configured, with the processor for the particular device, to cause a hardware apparatus, such as UE, to perform any of the processes described above (i.e., FIGS. 2-5). Therefore, in certain example embodiments, a non-transitory computer-readable medium may be encoded with computer instructions that, when executed in hardware, perform a process such as one of the processes described herein. Alternatively, certain example embodiments may be performed entirely in hardware.

In certain example embodiments, an apparatus may include circuitry configured to perform any of the processes or functions illustrated in FIGS. 2-5. As used in this application, the term “circuitry” may refer to one or more or all of the following: (a) hardware-only circuit implementations (such as implementations in only analog and/or digital circuitry), (b) combinations of hardware circuits and software, such as (as applicable): (i) a combination of analog and/or digital hardware circuit(s) with software/firmware and (ii) any portions of hardware processor(s) with software (including digital signal processor(s)), software, and memory (ies) that work together to cause an apparatus, such as a mobile phone or server, to perform various functions), and (c) hardware circuit(s) and or processor(s), such as a microprocessor(s) or a portion of a microprocessor(s), that requires software (e.g., firmware) for operation, but the software may not be present when it is not needed for operation. This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in server, a cellular network device, or other computing or network device.

According to certain example embodiments, processor 611 and memory 612, may be included in or may form a part of processing circuitry or control circuitry. In addition, in some example embodiments, transceiver 613 may be included in or may form a part of transceiving circuitry.

In some example embodiments, an apparatus (e.g., computing device 610) may include means for performing a method, a process, or any of the variants discussed herein. Examples of the means may include one or more processors, memory, controllers, transmitters, receivers, and/or computer program code for causing the performance of the operations.

The features, structures, or characteristics of example embodiments described throughout this specification may be combined in any suitable manner in one or more example embodiments. For example, the usage of the phrases “various embodiments,” “certain embodiments,” “some embodiments,” or other similar language throughout this specification refers to the fact that a particular feature, structure, or characteristic described in connection with an example embodiment may be included in at least one example embodiment. Thus, appearances of the phrases “in various embodiments,” “in certain embodiments,” “in some embodiments,” or other similar language throughout this specification does not necessarily all refer to the same group of example embodiments, and the described features, structures, or characteristics may be combined in any suitable manner in one or more example embodiments.

As used herein, “at least one of the following: <a list of two or more elements>” and “at least one of <a list of two or more elements>” and similar wording, where the list of two or more elements are joined by “and” or “or,” mean at least any one of the elements, or at least any two or more of the elements, or at least all the elements.

Additionally, if desired, the different functions or procedures discussed above may be performed in a different order and/or concurrently with each other. Furthermore, if desired, one or more of the described functions or procedures may be optional or may be combined. As such, the description above should be considered as illustrative of the principles and teachings of certain example embodiments, and not in limitation thereof.

One having ordinary skill in the art will readily understand that the example embodiments discussed above may be practiced with procedures in a different order, and/or with hardware elements in configurations which are different than those which are disclosed. Therefore, although some embodiments have been described based upon these example embodiments, it would be apparent to those of skill in the art that certain modifications, variations, and alternative constructions would be apparent, while remaining within the spirit and scope of the example embodiments.

CLAUSE 1: A computerized method, comprising determining a relative position token for each of a plurality of elements according to a function of at least one relative position token of at least one other element, wherein each relative position token comprises at least one discrete non-Cartesian value of each of the elements; and at least one relative position token corresponds with an element that is affixed to a wall, determining a Cartesian position for each of a plurality of elements according to a function of at least one of the relative position tokens to generate a room layout, displaying, in an interactive computerized user interface, at least one generated room layout, and based upon input from the interactive computerized user interface, transmitting at least one of the generated plurality of room layouts and a request for a selection of at least one of the transmitted room layouts.

CLAUSE 2: The method of clause 1, further comprising predicting an element parameter based on a set of tokens representing the room and already-present elements.

CLAUSE 3: The method of clause 1 or 2, further comprising iteratively repeating the predicting a predetermined number of times, wherein input tokens are updated to include already-predicted element parameters.

CLAUSE 4: The method of any of clauses 1-3, further comprising automatically generating one or more rooms.

CLAUSE 5: A system, comprising: at least one processor; and at least one memory storing instructions, wherein the instructions, when executed by the at least one processor, cause the apparatus at least to: determine a relative position token for each of a plurality of elements according to a function of at least one relative position token of at least one other element, wherein each relative position token comprises at least one discrete non-Cartesian value of each of the elements; and at least one relative position token corresponds with an element that is affixed to a wall, determine a Cartesian position for each of a plurality of elements according to a function of at least one of the relative position tokens to generate a room layout, display, in an interactive computerized user interface, at least one generated room layout, and based upon input from the interactive computerized user interface, transmit at least one of the generated plurality of room layouts and a request for a selection of at least one of the transmitted room layouts.

CLAUSE 6: The system according to clause 5, wherein the at least one memory stores instructions that when executed by the at least one processor, further cause the apparatus at least to: predict an element parameter based on a set of tokens representing the room and already-present elements.

CLAUSE 7: The system of clause 5 or 6, wherein the at least one memory stores instructions that when executed by the at least one processor, further cause the apparatus at least to: iteratively repeat the predicting a predetermined number of times, wherein input tokens are updated to include already-predicted element parameters.

CLAUSE 8: The system of any of clauses 5-7, wherein the at least one memory stores instructions that when executed by the at least one processor, further cause the apparatus at least to: automatically generate one or more rooms.

CLAUSE 9. At least one processor, comprising: processing circuitry to determine a relative position token for each of a plurality of elements according to a function of at least one relative position token of at least one other element, wherein each relative position token comprises at least one discrete non-Cartesian value of each of the elements; and at least one relative position token corresponds with an element that is affixed to a wall, determine a Cartesian position for each of a plurality of elements according to a function of at least one of the relative position tokens to generate a room layout, display, in an interactive computerized user interface, at least one generated room layout, and based upon input from the interactive computerized user interface, transmit at least one of the generated plurality of room layouts and a request for a selection of at least one of the transmitted room layouts.

Any and all combinations of any of the claim elements recited in any of the claims and/or any elements or clauses described in this application, in any fashion, fall within the contemplated scope of the present disclosure and protection.

### Partial Glossary

2D Two-Dimensional
3D Three-Dimensional
Btu British Thermal Units
CAD Computer-Aided Design
CPU Central Processing Unit
CSV Comma-Separated Value
CU Centralized Unit
GPS Global Positioning System
HDD Hard Disk Drive
HVAC Heating, Ventilation, and Air Conditioning
IoT Internet of Things
MEMS Micro Electrical Mechanical System
MIMO Multiple Input Multiple Output
mMTC Massive Machine Type Communication
PDA Personal Digital Assistance
RAM Random Access Memory
RF Radio Frequency
ROM Read-Only Memory
ST Standard Deviation
UI User Interface
WLAN Wireless Local Area Network

We claim:

1. A computerized method for automatically generating an optimized room layout design comprising:
determining a relative position token for each of a plurality of elements according to a function of at least one relative position token of at least one other element, wherein
each relative position token comprises at least one discrete non-Cartesian value of each of the elements; and
at least one relative position token corresponds with an element that is affixed to a wall;
determining a Cartesian position for each of a plurality of elements according to a function of at least one of the relative position tokens to generate a room layout;
displaying, in an interactive computerized user interface, at least one generated room layout; and
based upon input from the interactive computerized user interface, transmitting at least one of the generated plurality of room layouts and a request for a selection of at least one of the transmitted room layouts.

2. The computerized method of claim 1, further comprising:
predicting an element parameter based on a set of tokens representing the room and already-present elements.

3. The computerized method of claim 2, further comprising:
iteratively repeating the predicting a predetermined number of times, wherein input tokens are updated to include already-predicted element parameters.

4. The computerized method of claim 1, further comprising:
automatically generating one or more rooms.

5. An apparatus comprising:
at least one processor; and
at least one memory storing instructions that, when executed by the at least one processor, cause the apparatus at least to:
determine a relative position token for each of a plurality of elements according to a function of at least one relative position token of at least one other element, wherein
each relative position token comprises at least one discrete non-Cartesian value of each of the elements; and
at least one relative position token corresponds with an element that is affixed to a wall;
determine a Cartesian position for each of a plurality of elements according to a function of at least one of the relative position tokens to generate a room layout;
display, in an interactive computerized user interface, at least one generated room layout; and
based upon input from the interactive computerized user interface, transmit at least one of the generated plurality of room layouts and a request for a selection of at least one of the transmitted room layouts.

6. The apparatus of claim 5, wherein the at least one memory and the instructions, when executed by the at least one processor, further cause the apparatus at least to:
predict an element parameter based on a set of tokens representing the room and already-present elements.

7. The apparatus of claim 6, wherein the at least one memory and the instructions, when executed by the at least one processor, further cause the apparatus at least to:
iteratively repeat the predicting a predetermined number of times, wherein input tokens are updated to include already-predicted element parameters.

8. The apparatus of claim 5, wherein the at least one memory and the instructions, when executed by the at least one processor, further cause the apparatus at least to:
automatically generate one or more rooms.

9. A non-transitory computer readable medium comprising program instructions that, when executed by an apparatus, cause the apparatus to perform:
determining a relative position token for each of a plurality of elements according to a function of at least one relative position token of at least one other element, wherein
each relative position token comprises at least one discrete non-Cartesian value of each of the elements; and
at least one relative position token corresponds with an element that is affixed to a wall;
determining a Cartesian position for each of a plurality of elements according to a function of at least one of the relative position tokens to generate a room layout;
displaying, in an interactive computerized user interface, at least one generated room layout; and
based upon input from the interactive computerized user interface, transmitting at least one of the generated plurality of room layouts and a request for a selection of at least one of the transmitted room layouts.

10. The non-transitory computer readable medium of claim 9, further comprising:
predicting an element parameter based on a set of tokens representing the room and already-present elements.

11. The non-transitory computer readable medium of claim 10, further comprising:
iteratively repeat the predicting a predetermined number of times, wherein input tokens are updated to include already-predicted element parameters.

12. The non-transitory computer readable medium of claim 9, further comprising:
automatically generating one or more rooms.
